(19) United States
(12) Patent Application Publication
(10) Pub. No.: US 2013/0240028 A1
(43) Pub. Date: Sep. 19, 2013

(54) METHOD OF MANUFACTURING SOLAR CELL ELEMENT AND SOLAR CELL ELEMENT

(71) Applicant: KYOCERA CORPORATION, Kyoto-shi (JP)

(72) Inventors: Kotaro UMEDA, Amagasaki-shi (JP); Norikazu ITO, Moriyama-shi (JP); Akihiro MIZUMOTO, Omihachiman-shi (JP); Kenji OOBA, Moriyama-shi (JP)

(73) Assignee: KYOCERA CORPORATION, Kyoto-shi (JP)

(21) Appl. No.: 13/780,736

(22) Filed: Feb. 28, 2013

(30) Foreign Application Priority Data
Feb. 28, 2012 (JP) 2012-041857
Feb. 27, 2013 (JP) 2013-037050

(51) Int. Cl. H01L 31/0236

(52) U.S. Cl. CPC H01L 31/02366
USPC 136/255; 438/87

(57) ABSTRACT

A semiconductor substrate is prepared. A glass layer containing one conductivity type dopant is formed on one main surface of the semiconductor substrate. One conductivity type semiconductor region including a first concentration region having a first concentration as a dopant concentration, and a second concentration region having a second concentration as a dopant concentration higher than the first concentration is formed by heating the semiconductor substrate with the glass layer on the one main surface to diffuse the dopant in a surface part on the one main surface side of the semiconductor substrate. Surfaces of two or more portions apart from each other in the surface part on the one main surface side of the semiconductor substrate are roughened by locally heating the semiconductor substrate from above the glass layer, to form alignment reference parts.

### BACKGROUND OF THE INVENTION

1. Field of the Invention

The present invention relates to a solar cell element and a method of manufacturing a solar cell element.

2. Description of Background Art

A solar cell element comprises a region in which an opposite conductivity type impurity is diffused (also referred to as an opposite conductivity type region) in a surface part of one conductivity type semiconductor substrate. Thus, a solar cell element comprising a structure in which a region provided with a linear surface electrode, in the opposite conductivity type region, has an increased concentration of the opposite conductivity type impurity (also referred to as a selective emitter structure) is proposed (refer to Japanese Patent Application Laid-Open No. 2003-197932, for example).

In this selective emitter structure, the linear surface electrode can be formed with high accuracy on the region in which sheet resistance is reduced, on the surface of the semiconductor substrate, so that conversion efficiency can be improved. Thus, there is proposed a technique in which a pattern region having reflectance of the semiconductor substrate different from that of the other region is formed as an alignment mark by changing surface roughness in the region in which the surface electrode is formed, in the semiconductor substrate (refer to Japanese Patent Application Laid-Open No. 2011-23690, for example).

Here, as for the solar cell element, absorption efficiency of sunlight applied to its surface is enhanced by providing a concavo-convex part in almost a whole surface of the semiconductor substrate. At this time, the above pattern region whose roughness is changed as disclosed in Japanese Patent Application Laid-Open No. 2011-23690, and the above concavo-convex part are not easily distinguished from each other in some cases. Therefore, in a case where the pattern region is recognized by an image process, it is hard to determine an edge part of the pattern region, and it is hard to form the linear surface electrode with high accuracy.

### SUMMARY OF THE INVENTION

According to the present invention, a method of manufacturing a solar cell element comprises the steps of: (a) preparing a semiconductor substrate; (b) forming a glass layer containing one conductivity type dopant, on one main surface of the semiconductor substrate; (c) forming one conductivity type semiconductor region including a first concentration region having a first concentration as a dopant concentration, and a second concentration region having a second concentration as a dopant concentration higher than the first concentration by heating the semiconductor substrate provided with the glass layer on the one main surface to diffuse the dopant in a surface part on the one main surface side of the semiconductor substrate; and (d) roughening surfaces of two or more portions apart from each other in the surface part on the one main surface side of the semiconductor substrate by locally heating the semiconductor substrate from above the glass layer, to form the alignment reference parts.

An edge part of the alignment reference part can be easily determined, so that the electrode can be formed with high accuracy.

In addition, the present invention also aims at a solar cell element manufactured by the method of manufacturing the solar cell element comprising the steps (a) to (d).

According to the present invention, this solar cell element comprises a semiconductor substrate including the first concentration region having the first concentration as the one conductivity type dopant concentration, and the second concentration region having a concentration higher than that of the first concentration region as the one conductivity type dopant concentration, other than the first concentration region, in the surface part of the one main surface side; an antireflection film provided on the first concentration region of the one main surface; and an electrode provided on the second concentration region of the one main surface, in which two or more alignment reference parts apart from each other are provided in the surface part of the semiconductor substrate, and a first surface roughness of the one main surface in the two or more alignment reference parts is larger than a second surface roughness of the one main surface other than the alignment reference parts.

Therefore, an object of the present invention is to provide a method of manufacturing a solar cell element by which an electrode can be formed with high accuracy, and a solar cell element in which an electrode can be formed with high accuracy.

### BRIEF DESCRIPTION OF THE DRAWINGS

FIG. 1 is a plan view schematically showing an outer appearance of a light-receiving surface of a solar cell element according to an embodiment.

FIG. 2 is a plan view schematically showing an outer appearance of a non-light-receiving surface of the solar cell element according to the embodiment.

FIG. 3 is a view showing an X-Z cross-sectional surface in a position indicated by alternate long and short dash line III-III in FIGS. 1 and 2.

FIG. 4 is an exploded view schematically showing a cross-sectional surface of a solar cell module according to the embodiment.

FIG. 5 is a plan view schematically showing an outer appearance of the solar cell module according to the embodiment.

FIG. 6 is a photograph of a cross-sectional surface of an alignment reference part taken by a SEM.

FIG. 7 is a photograph of an upper surface of the alignment reference part taken by the SEM.

FIG. 8 is a flowchart showing a manufacturing flow of the solar cell element according to the embodiment.

FIG. 9 is a flowchart showing a manufacturing flow of the solar cell element according to the embodiment.

FIG. 10 is a flowchart showing a manufacturing flow of the solar cell element according to the embodiment.

FIG. 11 is a cross-sectional view showing a state in the middle of manufacturing the solar cell element according to the embodiment.

FIG. 12 is a cross-sectional view showing a state in the middle of manufacturing the solar cell element according to the embodiment.

FIG. 13 is a cross-sectional view showing a state in the middle of manufacturing the solar cell element according to the embodiment.

FIG. 14 is a cross-sectional view showing a state in the middle of manufacturing the solar cell element according to the embodiment.

FIG. 15 is a cross-sectional view showing a state in the middle of manufacturing the solar cell element according to the embodiment.

FIG. 16 is a photograph of a surface of the semiconductor substrate taken by the SEM after irradiated with a high-energy laser beam.

FIG. 17 is a schematic view showing an intensity distribution of energy in the laser beam.

FIG. 18 is a cross-sectional view showing a state in the middle of manufacturing the solar cell element according to the embodiment.

FIG. 19 is a plan view showing a state in the middle of manufacturing the solar cell element according to the embodiment.

FIG. 20 is a cross-sectional view showing a state in the middle of manufacturing the solar cell element according to the embodiment.

FIG. 21 is a plan view showing a state in the middle of manufacturing the solar cell element according to the embodiment.

FIG. 22 is a plan view showing a state in the middle of manufacturing a solar cell element according to a variation.

FIG. 23 is a plan view schematically showing an outer appearance of a light-receiving surface of the solar cell element according to the variation.

FIG. 24 is a plan view showing a state in the middle of manufacturing a solar cell element according to another variation.

FIG. 25 is a plan view schematically showing an outer appearance of a light-receiving surface of the solar cell element according to another variation.

FIG. 26 is a flowchart showing a variation of a process flow according to a roughening step.

FIG. 27 is a flowchart showing another variation of a process flow according to the roughening step.

FIG. 28 is a flowchart showing another variation of a process flow according to the roughening step.

### DETAILED DESCRIPTION OF THE INVENTION

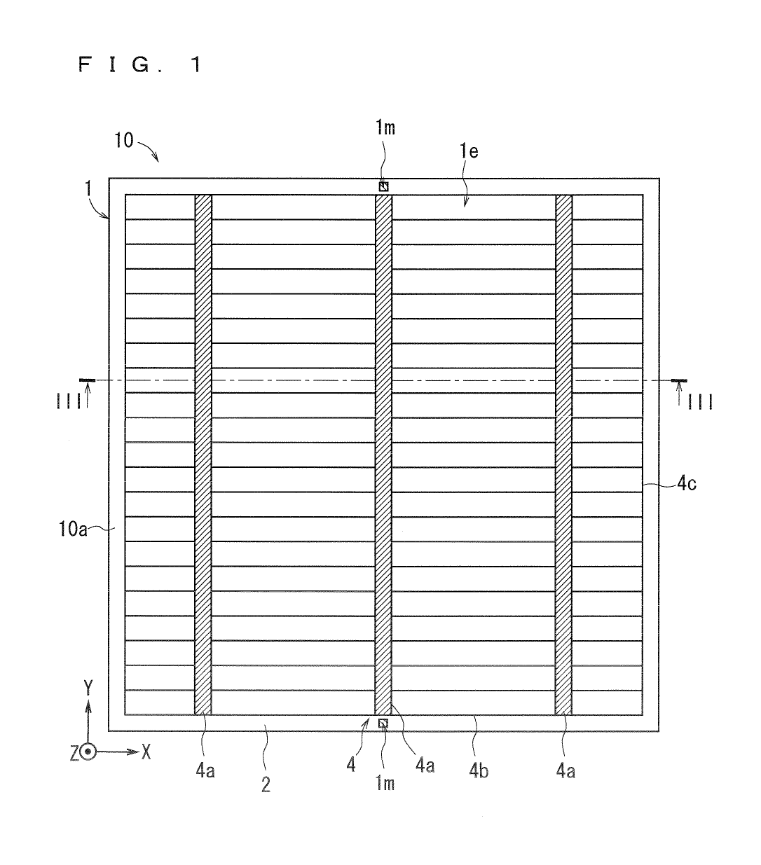

Hereinafter, a description will be given of an embodiment and various variations of the present invention with reference to the drawings. Note that, FIGS. 1 to 7, FIGS. 11 to 16, and FIGS. 18 to 25 each show a right-hand X-Y-Z coordinate system in which an extending direction of a first liner part 4b of a solar cell element 10 (right direction in a drawing in FIG. 1) is a +X direction.

### (1) Embodiment

<(1-1) Schematic Configuration of Solar Cell Element>

As shown in FIGS. 1 to 3, the solar cell element 10 has a first main surface 10a, a second main surface 10b, and a side surface 10c. The first main surface 10a is a surface for receiving incident light (also referred to as a light-receiving surface). In addition, the second main surface 10b is a surface positioned on a side opposite to the first main surface 10a of the solar cell element 10 (also referred to as a non-light-receiving surface). The side surface 10c is a surface for connecting the first main surface 10a and the second main surface 10b. In FIG. 3, the first main surface 10a is drawn as an upper surface of the solar cell element 10 on a +Z side, and the second main surface 10b is drawn as a lower surface of the solar cell element 10 on a −Z side.

In addition, the solar cell element 10 is provided with a plate-shaped semiconductor substrate 1, an antireflection film 2, a first electrode 4, and a second electrode 5.

The semiconductor substrate 1 comprises a configuration in which a first semiconductor region 1p having a first conductivity type, and a second semiconductor region In having a second conductivity type opposite to the first conductivity type are stacked. Here, the first semiconductor substrate 1 may be a substrate of monocrystalline or polycrystalline silicon (also referred to as a crystalline silicon substrate). In addition, according to this embodiment, the first conductivity type is a p-type, and the second conductivity type is an n-type. Note that, when the first conductivity type is the n-type, the second conductivity type may be the p-type.

The first semiconductor region 1p serves as a region of a semiconductor having the p-type conductivity type. The second semiconductor region in serves as a region of a semiconductor having the n-type conductivity type. More specifically, the first semiconductor region 1p is a region occupying a second main surface 1b (surface on the −Z side in the drawing) side of the semiconductor substrate 1. In addition, the second semiconductor region 1n is located on a first main surface 1a side (on the +Z side in the drawing) of the first semiconductor region 1p of the semiconductor substrate 1. Thus, the first semiconductor region 1p and the second semiconductor region 1n form a p-n junction region. Note that, a thickness of the first semiconductor region 1p may be, for example, 250 μm or less, and 150 μm or less. A shape of the first semiconductor region 1p may be a rectangular shape in a planar view, for example.

The second semiconductor region 1n comprises a first concentration region 1Ln and a second concentration region 1Hn other than the first concentration region 1Ln, in a surface part on the first main surface 1a side serving as the one main surface of the semiconductor substrate 1. The first concentration region 1Ln is a semiconductor region in which a concentration of a dopant (also referred to as a dopant concentration) of the n-type as the one conductivity type is a first concentration. In addition, an n-type dopant concentration in the second concentration region 1Hn is higher than the n-type dopant concentration in the first concentration region 1Ln.

Here, the second semiconductor region 1n can be formed in the surface part on the first main surface 1a side of the crystalline silicon substrate by diffusing the n-type dopant in the region on the first main surface 1a side of the crystalline silicon substrate having the p-type, for example. In this case, the part other than the second semiconductor region 1n in the crystalline silicon substrate can be the first semiconductor region 1p. Note that, as the n-type dopant, phosphorous may be employed, for example.

Further, the first semiconductor region 1p comprises a third concentration region 1Lp and a fourth concentration region 1Hp. The fourth concentration region 1Hp is located in a surface part on the second main surface 1b side of the semiconductor substrate 1. A concentration of a p-type dopant (also referred to as a dopant concentration) in the fourth concentration region 1Hp is higher than a p-type dopant concentration in the third concentration region 1Lp. Note that, as the p-type dopant, boron, gallium, aluminum or the like may be employed, for example.

The fourth concentration region 1Hp has a role to reduce carrier recombination in the region on the second main surface 1b side of the semiconductor substrate 1. Therefore, due to the presence of the fourth concentration region 1Hp, lowering of conversion efficiency is reduced in the solar cell element 10. In addition, the fourth concentration region 1Hp generates an internal electric field on the second main surface 1b side in the semiconductor substrate 1. Note that, the fourth concentration region 1Hp is formed by diffusing a dopant element such as boron or aluminum in the region on the second main surface 1b side in the semiconductor substrate 1. Thus, at this time, the part other than the fourth concentration region 1Hp in the first semiconductor region 1p can be the third concentration region 1Lp.

In addition, as shown in FIG. 3, a concavo-convex part 1aL is provided in the first main surface 1a in the semiconductor substrate 1. Here, a height of a convex part in the concavo-convex part 1aL may be about 0.2 μm or more, for example and a width of the convex part may be about 1 μm or more and about 20 μm or less, for example. In addition, a surface shape of a concave part of the concavo-convex part 1aL may be roughly spherical in shape, for example. Note that, as for the height of the convex part described here, by using a surface which passes through a bottom surface of the concave part and is parallel to the second main surface 1b as reference (also referred to as a reference surface), it means a distance between the reference surface and a top surface of the convex part, in a direction normal to the reference surface. In addition, the width of the convex part described here means a distance between the top surfaces of the adjacent convex parts, in a direction parallel to the reference surface.

Furthermore, two or more alignment reference parts 1m apart from each other are provided in the surface part on the first main surface 1a side of the semiconductor substrate 1. These two or more alignment reference parts 1m are used as reference when a position of the first electrode 4 is adjusted. In addition, the two or more alignment reference parts 1m are located on the first main surface 1a in this embodiment, but instead of this, three or more alignment reference parts 1m may be located on the first main surface 1a.

The antireflection film 2 is a film to improve light absorption efficiency in the solar cell element 10. The antireflection film 2 is located on the first concentration region 1Ln on the first main surface 1a side in the semiconductor substrate 1. As a material of the antireflection film 2, for example, silicon nitride, titanium oxide, silicon oxide, magnesium oxide, indium tin oxide, tin oxide, zinc oxide, or the like is employed. In addition, when a film of silicon nitride is employed as the antireflection film 2, a passivation effect can be also provided.

The antireflection film 2 is located along the concavo-convex part 1aL of the first main surface 1a, so that an upper surface of the antireflection film 2 on the +Z side comprises a concavo-convex part corresponding to the shape of the concavo-convex part 1aL. In addition, a thickness of the antireflection film 2 may be appropriately set, based on the materials of the semiconductor substrate 1 and the antireflection film 2. Thus, a condition that light is not likely to be reflected with respect to various light irradiation in the solar cell element 10 can be realized. In the case where the semiconductor substrate 1 is the crystalline silicon substrate, a refractive index of the antireflection film 2 may be about 1.8 or more and about 2.3 or less, for example. In addition, a thickness of the antireflection film 2 /may be about 50 nm or more and about 120 nm or less, for example.

The first electrode 4 is located on the first main surface 1a of the semiconductor substrate 1. More specifically, the first electrode 4 is located on the second concentration region 1Hn on the first main surface 1a side in the semiconductor substrate 1. Thus, as shown in FIG. 1, the first electrode 4 comprises a plurality of first linear parts 4b extending in an X direction as a first direction, and a second linear part 4a extending in a Y direction as a second direction different from the first direction and intersecting with the plurality of the first linear parts 4b. Furthermore, the first electrode 4 comprises a third linear part 4c extending in the Y direction as the second direction and connected to the plurality of the first linear parts 4b, at each end part of the first linear part 4b.

Here, at least one part of the second linear part 4a intersects with the plurality of the first linear parts 4b, so that it is electrically connected to the plurality of the first linear parts 4b. Thus, a width of the second linear part 4a may be larger than a width of each of the plurality of the first linear parts 4b. More specifically, each of the widths of the first liner part 4b and the third linear part 4c in a short direction may be about 50 μm or more and about 200 μm or less, for example. The width of the second linear part 4a in a short direction may be about 1.3 mm or more and about 2.5 mm or less, for example. In addition, a distance between the adjacent first linear parts 4b among the plurality of the first liner parts 4b may be about 1.5 mm or more and about 3 mm or less. Furthermore, a thickness of the first electrode 4 may be about 10 μm or more and about 40 μm or less, for example.

By the way, the first electrode 4 is formed by applying a conductive paste mainly containing silver (also referred to as a silver paste) on the first main surface 1a side of the semiconductor substrate 1 in a desired pattern by screen printing or the like, and then firing it. At this time, as shown in FIG. 1, the region in which the first electrode 4 is formed (also referred to as a formed region) is adjusted, with reference to the two or more alignment reference parts 1m provided in the surface part on the first main surface 1a side of the semiconductor substrate 1. That is, the first electrode 4 can be formed with high accuracy on the second concentration region 1Hn of the semiconductor substrate 1.

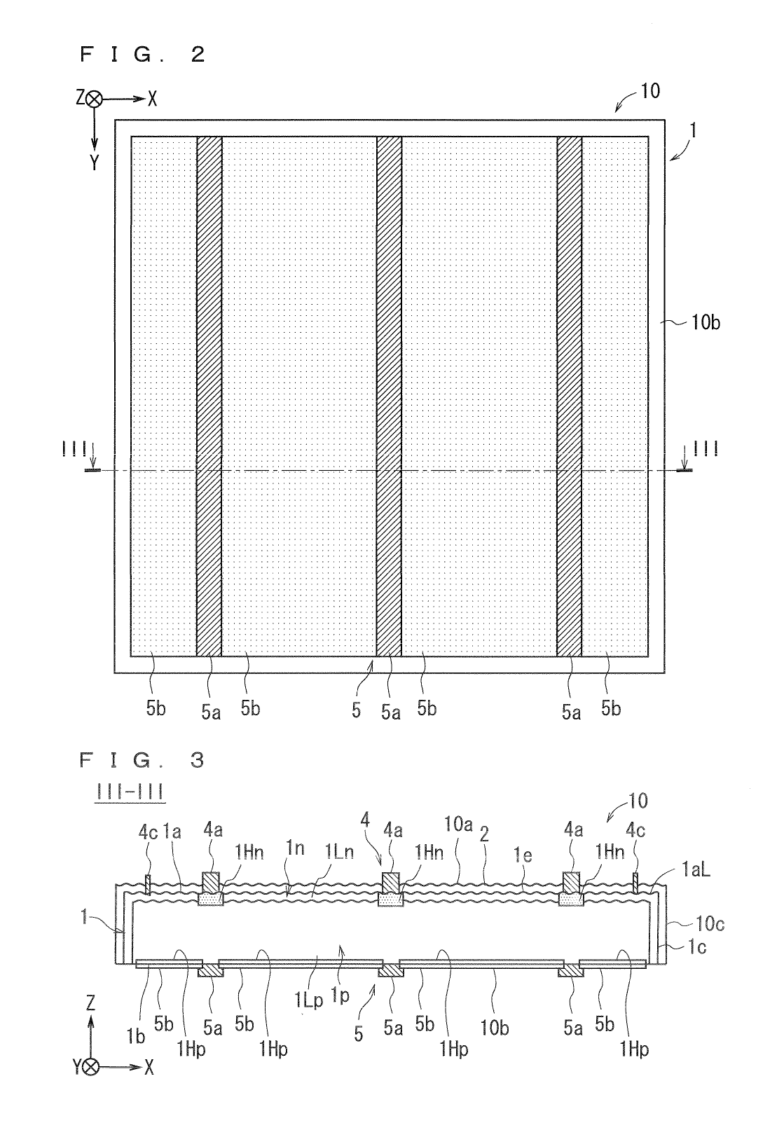

The second electrode 5 is located on the second main surface 1b side of the semiconductor substrate 1. As shown in FIG. 2, the second electrode 5 comprises an output extraction electrode 5a and a collecting electrode 5b. A thickness of the output extraction electrode 5a may be about 10 μm or more and about 30 μm or less, for example. A width of the output extraction electrode 5a in a short direction may be about 1.3 mm or more and about 7 mm or less, for example. In addition, the output extraction electrode 5a is formed with the same material and method as those of the first electrode 4. That is, the output extraction electrode 5a is formed by applying the silver paste on the second main surface 1b side of the semiconductor substrate 1 in a desired pattern by screen printing or the like, and firing it. In addition, the collecting electrode 5b may be formed on almost a whole surface of the second main surface 1b of the semiconductor substrate 1 except for the region in which the output extraction electrode 5a is formed. A thickness of the collecting electrode 5b may be about 15 μm or more to about 50 μm or less. In addition, the collecting electrode 5b is formed by applying a conductive paste mainly containing aluminum (also referred to as an aluminum paste) on the second main surface 1b side of the semiconductor substrate 1 in a desired pattern by screen printing or the like, and firing it.

<(1-2) Solar Cell Module>

A solar cell module 100 according to the embodiment is provided with one or more solar cell elements 10. For example, the solar cell module 100 may be provided with the plurality of the electrically connected solar cell elements 10. Such solar cell module 100 is formed by connecting the plurality of solar cell elements 10 in series and in parallel, for example, in a case where an electric output of the single solar cell element 10 is small. Thus, a practical electric output can be obtained by combining the plurality of solar cell modules 100, for example. Hereinafter, a description will be given of one example in which the solar cell module 100 is provided with the plurality of the solar cell elements 10.

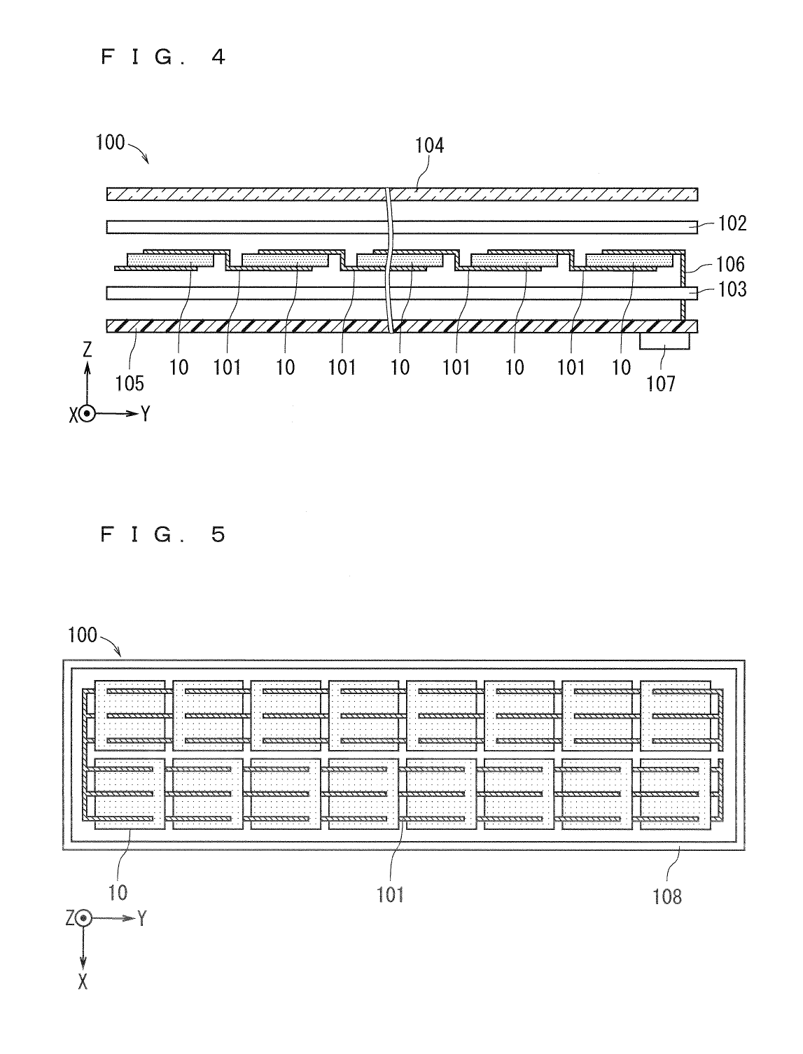

As shown in FIG. 4, the solar cell module 100 is provided with a laminated body in which a transparent member 104, a front side filling material 102, the plurality of solar cell elements 10, wiring members 101, a rear side filling material 103, and a rear side protecting material 105 are laminated thereon. Here, the transparent member 104 is a member to protect a light-receiving surface of the solar cell module 100. The transparent member 104 may be a transparent plate-shaped member, for example. As a material of the transparent member 104, glass is employed, for example. The front side filling material 102 and the rear side filling material 103 may be a transparent filling material, for example. As a material of the front side filling material 102 and the rear side filling material 103, ethylene-vinyl acetate copolymer (EVA) or the like is employed, for example. The rear surface protecting material 105 is a member to protect the solar cell module 100 from a rear surface. As a material of the rear surface protecting material 105, polyethylene terephthalate (PET), polyvinyl fluoride (PVF) or the like is employed, for example. In addition, the rear surface protecting material 105 may have a single-layer structure or may have a laminated structure.

The wiring member 101 is a member to electrically connect the plurality of solar cell elements 10 (also referred to as a connecting member). As for the adjacent solar cell elements 10 in the ±Y direction among the plurality of the solar cell elements 10 in the solar cell module 100, the first electrode 4 of one of the adjacent solar cell elements 10 is connected to the second electrode 5 of the other solar cell element 10 in series by the wiring member 101. Here, a thickness of the wiring member 101 may be about 0.1 mm or more and about 0.2 mm or less, for example. A width of the wiring member 101 may be about 2 mm. As the wiring member 101, a member in which a whole surface of copper foil is covered with solder is employed.

In addition, among the plurality of solar cell elements 10 electrically connected in series, one end of the electrode of the first solar cell element 10 and one end of the electrode of the last solar cell element 10 are electrically connected to a terminal box 107 serving as an output extraction part, by an output extraction wiring 106. In addition, as shown in FIG. 5, the solar cell module 100 may be provided with a frame body 108 to protect the laminated body from the environment. As a material of the frame body 108, aluminum or the like having both corrosion resistance and strength is employed, for example.

In a case where EVA is employed as at least one material of the front side filling material 102 and the rear side filling material 103, by adding an acidacceptor containing magnesium hydroxide, calcium hydroxide or the like to EVA, a generation of acetic acid caused by temporal hydrolysis from EVA can be reduced. Thus, durability of the solar cell module 100 can be improved.

According to the solar cell element 10 of this embodiment, a surface roughness of the two alignment reference parts 1m provided in the surface part on the first main surface 1a side of the semiconductor substrate 1 is different from a surface roughness in another region of the surface part of the first main surface 1a. More specifically, in the first main surface 1a of the semiconductor substrate 1, a first surface roughness in the two alignment reference parts 1m is larger than a second surface roughness in a residual region 1e other than the two alignment reference parts 1m.

In this case, diffused reflection of the emitted light is likely to be generated on the two alignment reference parts 1m, compared with the residual region 1e. Thus, while the light is not likely to be reflected due to a light confinement effect by the antireflection film 2 on the residual region 1e, the light is likely to be reflected on the two alignment reference parts 1m. More specifically, while the residual region 1e covered with the antireflection film 2 is recognized as a dark blue region, the two alignment reference parts 1m covered with the antireflection film 2 can be recognized as a whitish region. Therefore, in this case, the positions of the two alignment reference parts 1m can be easily detected in the first main surface 1a. As a result, when the first electrode 4 is formed, the formed region of the first electrode 4 can be adjusted with high accuracy, with reference to the two alignment reference parts 1m. Thus, the first electrode 4 can be formed with high accuracy on the second concentration region 1Hn of the semiconductor substrate 1.

Here, as a method of detecting the positions of the two alignment reference parts 1m, image processing in which the positions of the two alignment reference parts 1m are detected after a binarization process, based on an image of the first main surface 1a, a visual detection or the like may be employed, for example. In addition, the surface roughness of the first main surface 1a can be measured by a surface roughness measuring instrument of contact type such as a stylus method, or a non-contact type such as an optical interferometry. Thus, as a parameter showing the roughness, arithmetic mean roughness Ra or the like may be employed, for example.

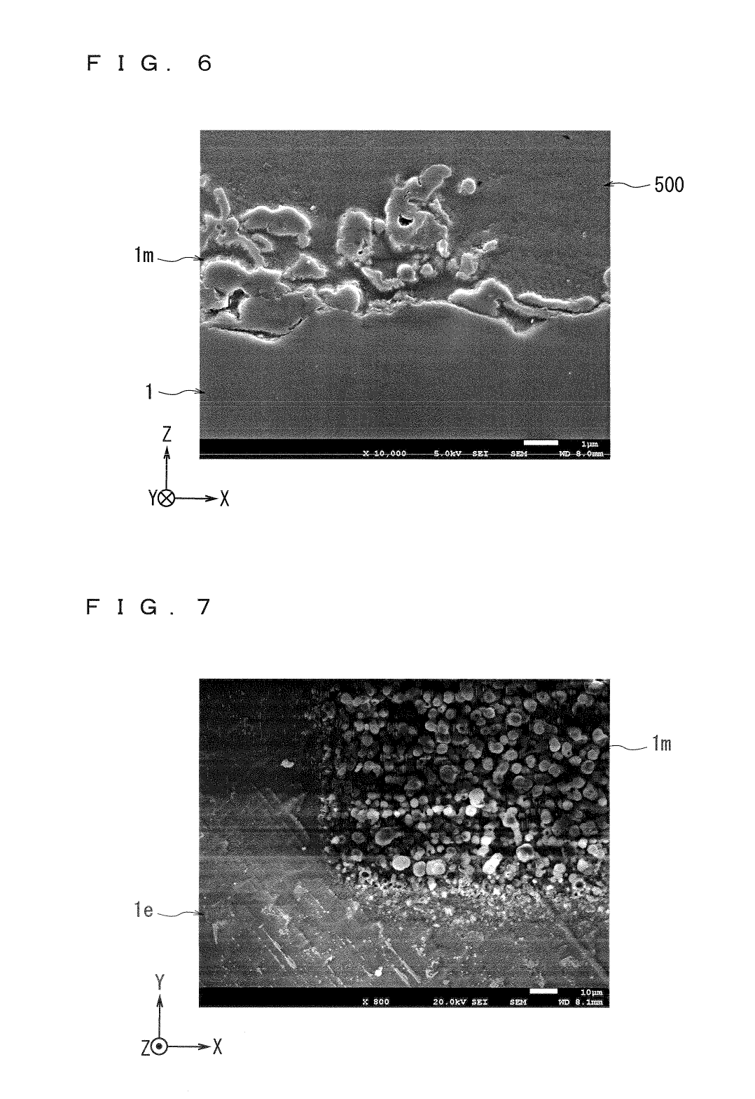

FIG. 6 is a photograph of one example of an X-Z cross-sectional surface in the vicinity of the alignment reference part 1m in the semiconductor substrate 1 taken by a scanning electron microscope (SEM). In the photograph in FIG. 6, the semiconductor substrate 1 is shown from a lower part to the vicinity of a center part, the alignment reference part 1m is shown in the vicinity of the center part, and a resin 500 used for fixing the semiconductor substrate 1 serving as an observation target is shown in an upper part. As shown in FIG. 6, the alignment reference part 1m may comprise a structure including a void, for example. Meanwhile, although the residual region 1e has a gentle concavo-convex shape along the concavo-concave part 1aL, for example, the residual region 1e may comprise a relatively smooth surface part which does not include a void in general.

That is, for example, a void ratio of the surface part of each of the two alignment reference parts 1m may be higher than a void ratio of the surface part of the residual region 1e other than the two alignment reference parts 1m. In this case, the effect of diffusely reflecting the emitted light can be higher in the two alignment reference parts 1m, than the residual region 1e. Thus, the two alignment reference parts 1m covered with the antireflection film 2 can be easily recognized as the more whitish part. Therefore, the positions of the two alignment reference parts 1m in the first main surface 1a can be detected with higher accuracy. In addition, an amount of the void ratio of the surface part can be evaluated through observation of a cross-sectional surface of the surface part or image processing with a photograph of the cross-sectional surface.

FIG. 7 is a photograph of one example of a surface in the vicinity of the alignment reference part 1m in the first main surface 1a taken by the SEM. In the photograph in FIG. 7, the alignment reference part 1m is shown from an upper right part to the vicinity of a center part, and the residual region 1e is shown in a left part and a lower part. As shown in FIG. 7, the alignment reference part 1m may comprise a part in which a plurality of granulated parts (also referred to as a granular parts) are aggregated (also referred to as an aggregated part). Here, a grain diameter of the plurality of granulated parts may be about 5 μm in general, and about several μm or more and about 10 μm or less, for example. Meanwhile, for example, the residual region 1e comprises almost no granular parts and may have a smooth surface in general, while comprising a concavo-convex part having a height about 0.1 μm or more to about 1 μm or less.

In this case, the diffused reflection of light is more likely to be generated, on the two alignment reference parts 1m comprising the aggregated part of the plurality of the granular parts. Thus, the positions of the two alignment reference parts 1m covered with the antireflection film 2 can be recognized as the more whitish parts, for example. Therefore, the positions of the two alignment reference part 1m in the first main surface 1a can be detected more easily and accurately.

In addition, the antireflection film 2 is provided on each of the two alignment reference parts 1m and the residual region 1e in the first main surface 1a. Thus, a thickness of the antireflection film 2 provided on the two alignment reference parts 1m may be smaller than a thickness of the antireflection film 2 provided on the residual region 1e.

In this case, on the two alignment reference parts 1m, the thickness of the antireflection film 2 is largely shifted from a set value, so that the reflection reduction effect of the antireflection film 2 is reduced, and the diffused reflection of light is more easily generated. Thus, the two alignment reference parts 1m covered with the antireflection film 2 can be recognized as the more whitish parts. Therefore, the two alignment reference parts 1m in the first main surface 1a can be detected more easily. As a result, when the first electrode 4 is formed, the formed region of the first electrode 4 can be adjusted with higher accuracy, with reference to the two alignment reference parts 1m. Thus, the first electrode 4 can be formed with higher accuracy on the second concentration region 1Hn of the semiconductor substrate 1.

Here, as for a region of a unit area in the first main surface 1a planarly viewed from the +Z side, a surface area of the alignment reference part 1m may be considerably larger than a surface area of the residual region 1e. In this case, when the antireflection film 2 is formed on each of the alignment reference part 1m and the residual region 1e at the same time under roughly the same condition, a thickness of the antireflection film 2 on the two alignment reference parts 1m can be smaller than a thickness of the antireflection film 2 on the residual region 1e.

In addition, an amount of the thickness of the antireflection film 2 can be confirmed by energy dispersive X-ray spectroscopy (EDX), for example. More specifically, in a case where the antireflection film 2 is a film of silicon nitride, for example, it can be confirmed that an abundance of nitrogen on the two alignment reference parts 1m is smaller than an abundance of nitrogen on the residual region 1e by analysis of the EDX attached to the SEM.

In addition, as shown in FIG. 1, the one alignment reference part 1m of the two alignment reference parts 1m may be positioned in a region on an extended line virtually extended from the second linear part 4a in the Y direction, in the first main surface 1a, for example. In this case, when the solar cell module 100 is manufactured, the wiring member 101 is provided on the alignment reference part 1m on the +Y side of the two alignment reference parts 1m. As a result, a reduction of the light receiving amount and a deterioration of power generation efficiency can be reduced due to the provision of the alignment reference part 1m in the solar cell element 10.

In addition, in the semiconductor substrate 1, a first oxygen concentration of the surface part of each of the two alignment reference parts 1m may be higher than a second oxygen concentration of the surface part of the residual region 1e, for example. Here, when the semiconductor substrate 1 is the crystalline silicon substrate, transparent amorphous silicon oxide can be provided on the surface part of the two alignment reference parts 1m, for example. In this case, due to relatively large surface roughness of this amorphous silicon oxide, the diffused reflection of light is more likely to be generated on the two alignment reference parts 1m. Thus, the two alignment reference parts 1m covered with the antireflection film 2 can be recognized as the more whitish parts, for example. Therefore, the positions of the two alignment reference parts 1m in the first main surface 1a can be more easily detected.

In addition, the fact that the first oxygen concentration of the surface part in the two alignment reference parts 1m is higher than the second oxygen concentration of the surface part in the residual region 1e can be confirmed by analysis of the EDX attached to the SEM. In addition, the fact that a silicon concentration of the surface part in the two alignment reference parts 1m is lower than a silicon concentration of the surface part in the residual region 1e can be also confirmed by analysis of the EDX attached to the SEM.

<(1-3) Manufacturing Method of Solar Cell Element>

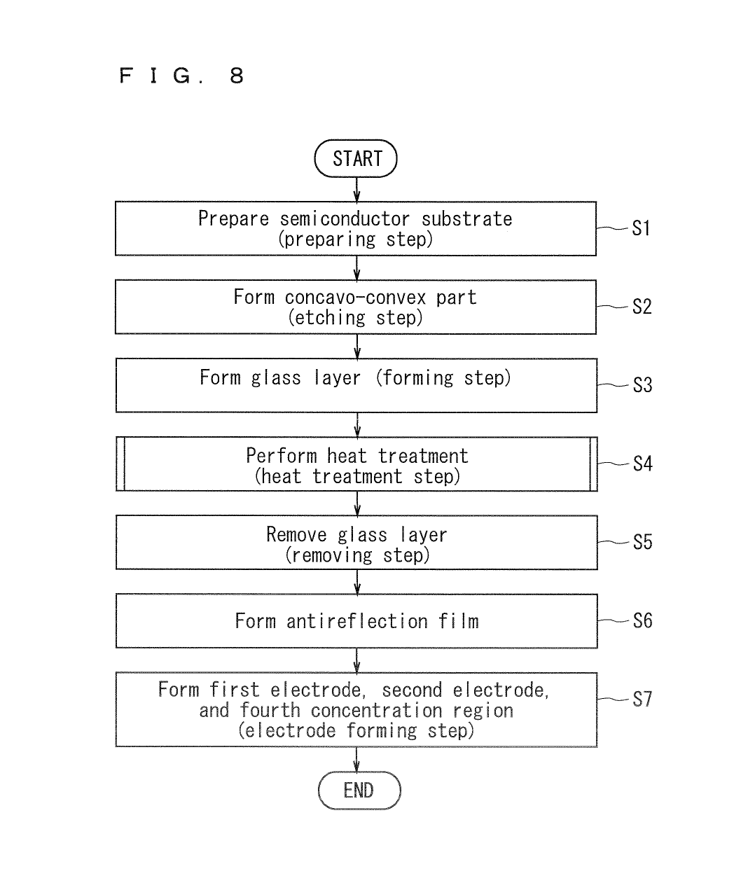

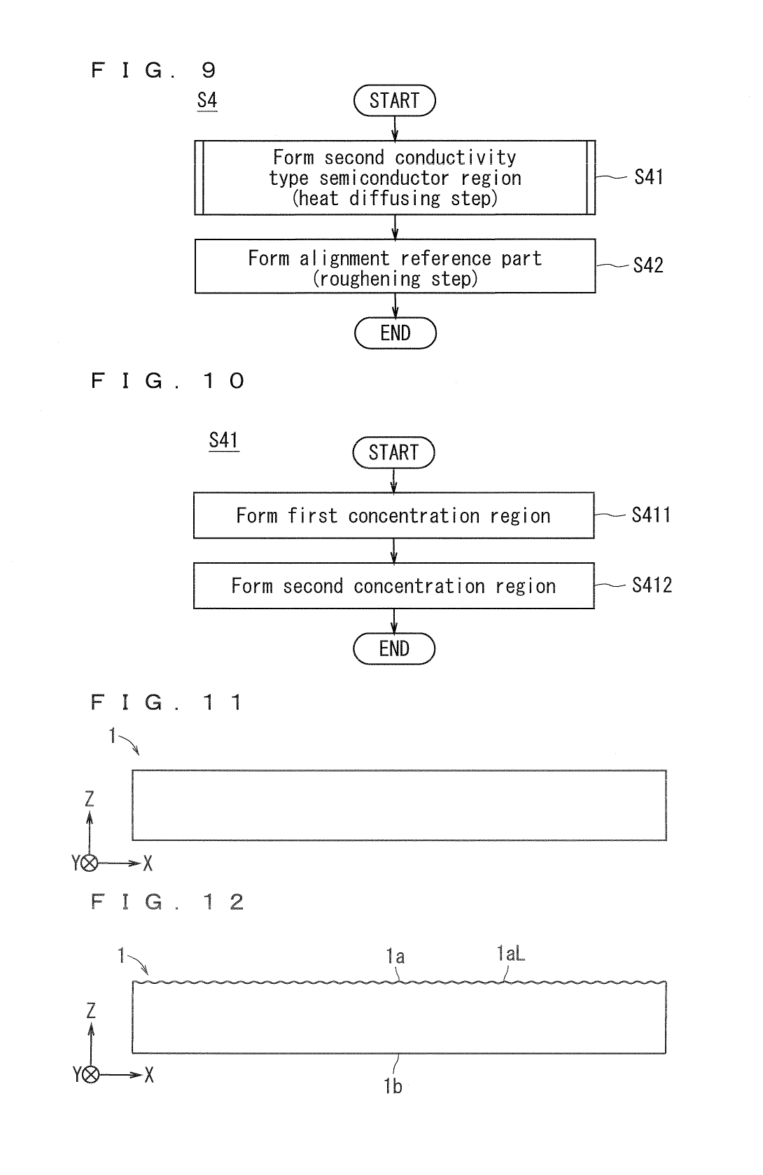

Here, an embodiment of a manufacturing process of the solar cell element 10 comprising the above configuration will be described. FIGS. 8 to 10 are flowcharts illustrating manufacturing flows of the solar cell element 10. Here, as shown in FIG. 8, the solar cell element 10 is manufactured by sequentially performing step Si to step S7. Thus, in step S4, step S41 and step S42 are sequentially performed as shown in FIG. 9, and in step S41, step S411 and step S412 are sequentially performed as shown in FIG. 10.

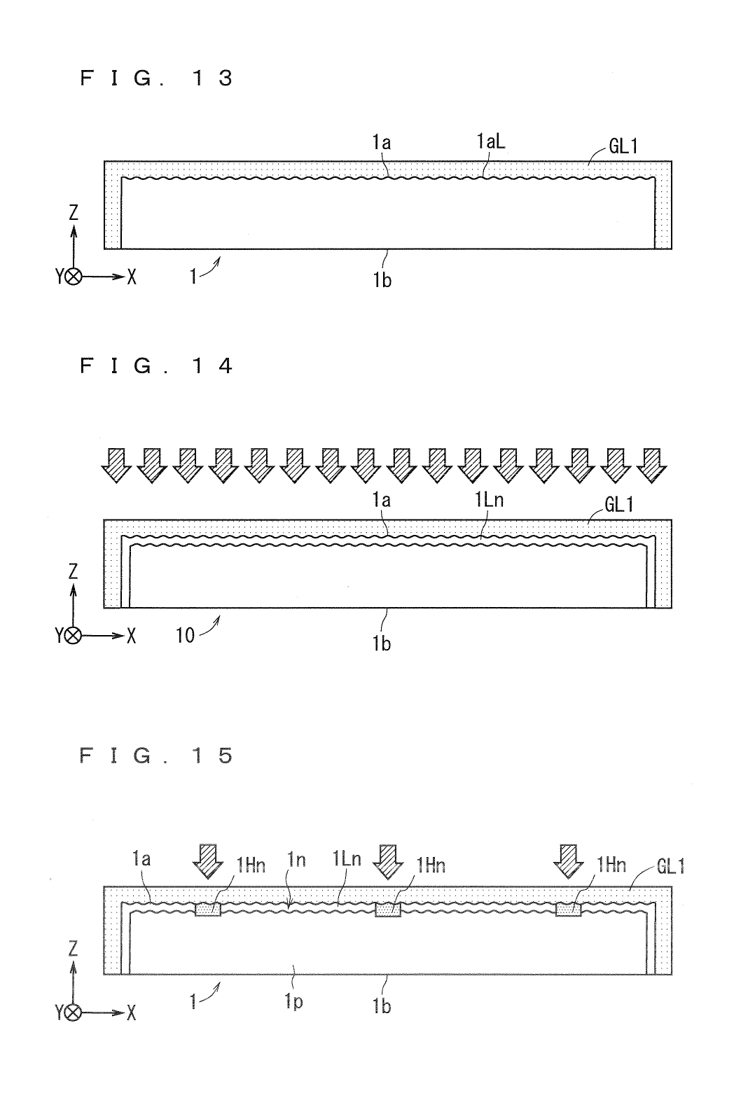

First, in step S1, a step for preparing the semiconductor substrate 1 (see FIG. 11) (also referred to as a preparing step) is performed. According to this embodiment, the semiconductor substrate 1 having the p-type is prepared. Here, in the case where the semiconductor substrate 1 is the monocrystalline silicon substrate, the semiconductor substrate 1 can be formed by using FZ (Floating Zone) method or the like, for example. In addition, in the case where the semiconductor substrate 1 is the polycrystalline silicon substrate, the semiconductor substrate 1 can be formed by using a casting method or the like, for example. More specifically, an ingot of the polycrystalline silicon is prepared as a semiconductor material first by the casting method, for example. Then, the ingot is thinly sliced to be 250 μm or less in thickness, for example. Then, for example, the surface of the semiconductor substrate 1 is very slightly etched with a water solution of NaOH, KOH, hydrofluoric acid, fluonitric acid, or the like so that a layer having a mechanical damage and a contaminated layer on a sliced surface of the semiconductor substrate 1 can be removed.

In step S2, a step of forming the concavo-convex part 1aL (see FIG. 12) (also referred to as an etching step) on the first main surface 1a is performed. Here, the etching process is performed with an acid water solution at least on the first main surface 1a in the semiconductor substrate 1, whereby the concavo-convex part 1aL is formed in the first main surface 1a. As a method of forming the concavo-convex part 1aL, wet etching in which an alkali solution of NaOH or the like or an acid solution of fluonitric acid is used, or dry etching in which RIE or the like is used can be employed.

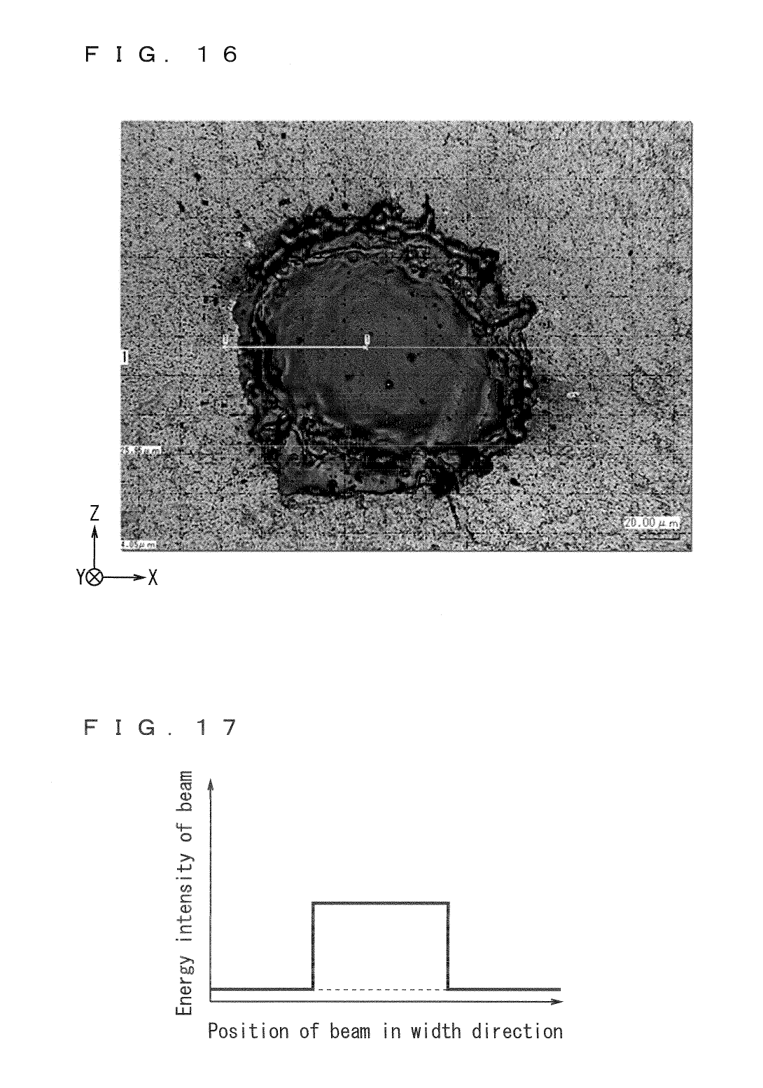

In step S3, a step of forming a glass layer GL1 (see FIG. 13) containing an element serving as the n-type dopant (referred to as a forming step), on the first main surface 1a of the semiconductor substrate 1 is performed. As a material of the glass layer GL1, phosphate glass is employed, for example. In this case, paste-form P₂O₅ is applied to the first main surface 1a of the semiconductor substrate 1, for example, whereby the glass layer GL1 can be formed. Alternatively, a heat treatment is performed on the semiconductor substrate 1 at a temperature range about between 600° C. and 800° C. in an atmosphere containing gas such as POCl₃ or the like, whereby the glass layer GL1 may be formed on the first main surface 1a of the semiconductor substrate 1. In addition, a thickness of the glass layer GL1 may be about 30 nm, for example.

In step S4 in FIG. 8, a step of performing a heat treatment (also referred to as a heat treatment step) is performed for the semiconductor substrate 1 comprising the glass layer GL1 on the first main surface 1a. At this time, the semiconductor substrate 1 is heated in an atmosphere mainly containing inert gas of argon, nitrogen, or the like. In step S4, a step of forming the second semiconductor region 1n having the n-type conductivity type on the first main surface 1a side of the semiconductor substrate 1 by heat diffusion (also referred to as a heat diffusion step) is performed first in step S41 in FIG. 9.

More specifically, in step S411 in FIG. 10, the semiconductor substrate 1 with the glass layer GL1 on the first main surface 1a is heated to form the first concentration region 1Ln (see FIG. 14) serving as the n-type semiconductor region in which phosphorous serving as the n-type dopant element has the first concentration. Here, the phosphorous is diffused from the glass layer GL1 to the surface part on the first main surface 1a side of the semiconductor substrate 1, whereby the first concentration region 1Ln is formed. At this time, the heat treatment may be performed on the semiconductor substrate 1 at a high temperature range about between 800° C. and 900° C. A time taken for this heat treatment may be about 10 minutes or more and about 40 minutes or less, for example. In addition, a thickness of the first concentration region 1Ln may be about 0.1 μm or more and about 1 μm or less.

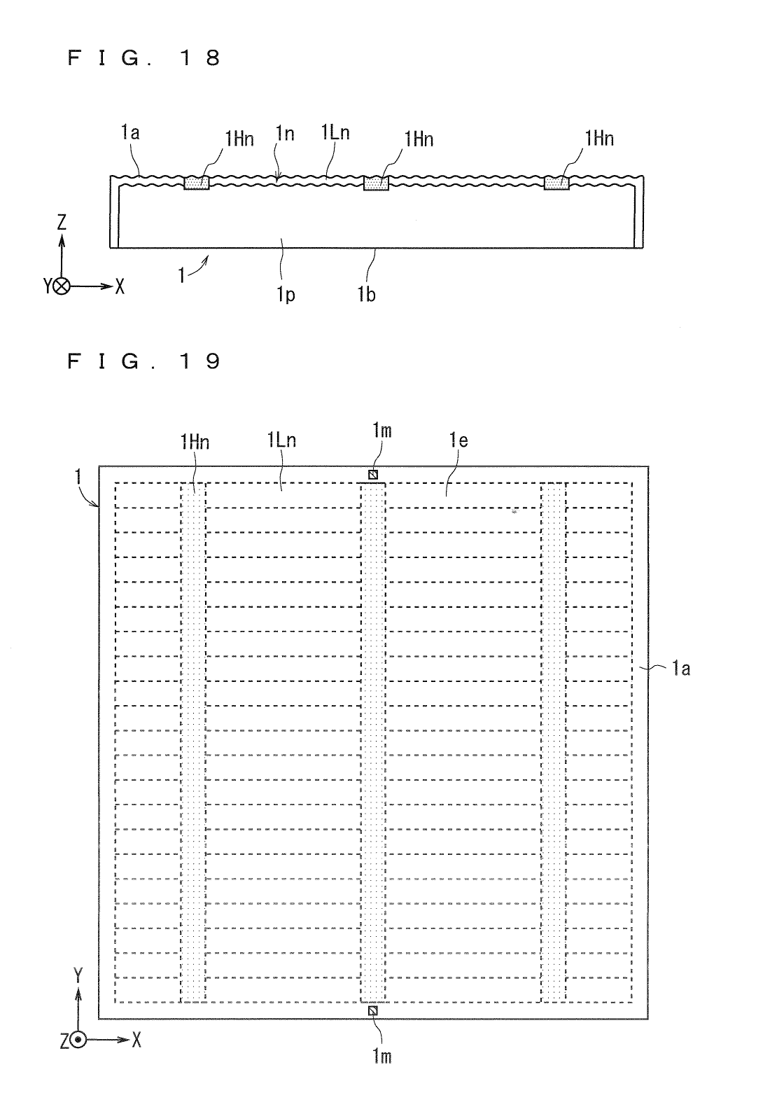

In subsequent step S412, the semiconductor substrate 1 with the glass layer GL1 on the first main surface 1a is heated to form the second concentration region 1Hn (see FIG. 15) serving as the n-type semiconductor region in which phosphorous serving as the n-type dopant element has the second concentration higher than the first concentration. Here, phosphorous is diffused from the glass layer GL1 to the surface part on the first main surface 1a side of the semiconductor substrate 1, whereby the second concentration region 1Hn is formed. At this time, by, for example, performing first irradiation in which a laser beam is applied from above the glass layer GL1 to a partial region of the semiconductor substrate 1, the partial region is heated, whereby the second concentration region 1Hn is formed.

Here, as a light source of the laser beam, a YAG laser, SHG-YAG laser, YVO₄ laser, excimer laser, DPPS laser, or the like is employed, for example. A wavelength of the laser beam emitted from the YAG laser and YVO₄ laser may be 1064 nm, for example. A wavelength of the laser beam emitted from the SHG-YAG laser and DPPS laser may be 532 nm, for example. A wavelength of the laser beam emitted from the excimer laser may be 193 nm or more and 353 nm or less, for example.

In addition, a frequency of emission of the laser beam may be 1 kHz or more and 200 kHz or less, for example. A time (also referred to as a pulse width) taken for one shot of the laser beam emitted from the laser may be 1 n second or more and 1.2μ second or less, for example. In addition, energy of the laser beam for one shot emitted from the laser may be 0.3 J/cm² or more and 3 J/cm² or less. In addition, the laser beam may be applied to the glass layer GL1 provided on the first main surface 1a of the semiconductor substrate 1 while being deflected by a galvanometer mirror. At this time, moving speed of a spot (also referred to as a scanning speed) of the laser beam emitted from above the glass layer GL1 to the first main surface 1a may be 1000 cm/second or more and 15000 cm/second or less, for example. In addition, a diameter of the spot of the laser beam may be almost the same as the width of the first linear part 4b, or between smaller by about 10 μm and larger by about 100 μm than the width of the first linear part 4b.

Under the above irradiation condition of the laser beam, the laser beam emitted from the laser at one shot is applied from above the glass layer GL1 to the partial region of the semiconductor substrate 1 while being sequentially shifted. At this time, actually, the laser beam emitted from the laser by one shot is applied to the region in which the second concentration region 1Hn is formed in the first main surface 1a. In addition, the number of irradiation in the first irradiation of the laser beam in step S412 is actually one, but the laser beams may be applied while being partially overlapped.

Then, in step S42 in FIG. 9, the semiconductor substrate 1 is locally heated from above the glass layer GL1, whereby a step of forming the two or more alignment reference parts 1m (also referred to as a roughening step) is performed. Here, two or more positions which are apart from each other in the first main surface 1a are locally heated from above the glass layer GL1, whereby the surfaces of the two or more portions apart from each other in the surface part on the first main surface 1a side of the semiconductor substrate 1 are roughened. Thus, the surfaces of the two or more portions in the surface part become the two or more alignment reference parts 1m. In addition, according to this embodiment, the two alignment reference parts 1m are formed. At this time, by performing second irradiation in which the laser beams is applied more times than that of the first irradiation of the laser beam in step S412, from above the glass layer GL1 to the semiconductor substrate 1, the semiconductor substrate 1 is locally heated and the surface of the two or more portions in the surface part are roughened. The two or more roughened parts in the surface of the surface part become the alignment reference parts 1m.

More specifically, almost the same laser beam as the laser beam emitted from the laser at one shot in step S412 is continuously applied to the same position 100 to 10000 times for a time between 0.01 second and 1 second. That is, the laser beam having the energy ranging between 0.3 J/cm² and 3 J/cm² emitted from the laser at one shot is applied to the same position 100 to 10000 times. Note that, the frequency of emission of the laser beam may be 1 kHz or more and 200 kHz or less, similar to the laser beam in step S412, for example. A pulse width may be 1 nanosecond or more and 1.2μ second or less, for example. At this time, the part continuously irradiated with the laser beam in the glass layer GL1 is melted, and the surface part on the first main surface 1a side of the semiconductor substrate 1 positioned under that part is also locally melted. Thus, while the laser beam is applied 100 to 10000 times, the melting, oxidization, and curled-up solidification caused by an action of surface tension are repeated in the surface part of the first main surface 1a side of the semiconductor substrate 1, so that the surface of the surface part is roughened. As a result, for example, as shown in FIG. 7, the aggregated part in which the plurality of granular parts each mainly having the grain diameter of about 5 μm are aggregated can be formed. In this way, the alignment reference part 1m can be formed. Note that, at this time, it is expected that the molten phosphate glass in the glass layer GL1 is solidified along the granular part.

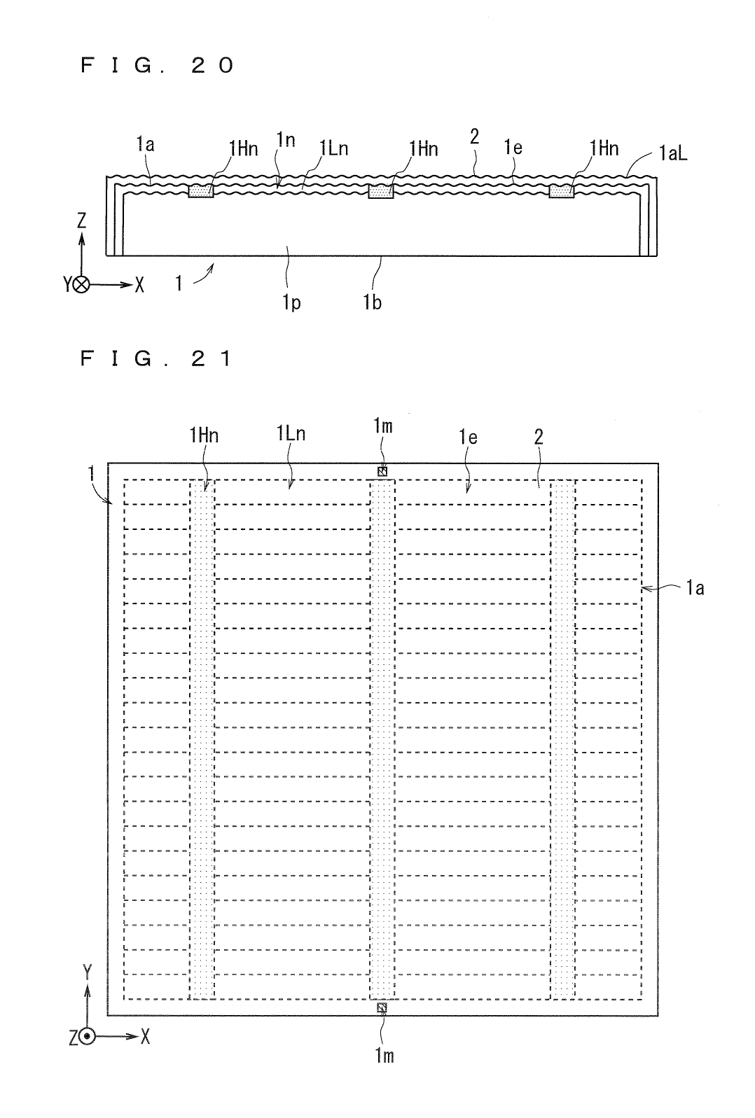

Here, a following case is assumed, that is, a case where a laser beam having energy ranging between 8 J/cm² and 15 J/cm² emitted from the laser at one shot is applied several times from above the glass layer GL1 to the same position of the first main surface 1a, unlike the above case where the laser beam having the relatively small energy is applied many times. In this case, as shown in FIG. 16, the region irradiated with the laser beam, in the first main surface 1a of the semiconductor substrate 1 is hardly roughened, and its outer edge part is a little roughened in the process of being solidified. Therefore, the diffused reflection of light is not sufficiently generated in the region having such surface shape, and this region is not easily detected. Meanwhile, according to this embodiment, the laser beam having the relatively small energy is intermittently applied from above the glass layer GL1 to the same position of the first main surface 1a many times. As a result, as shown in FIG. 7, the surface of the surface part on the first main surface 1a side of the semiconductor substrate 1 can be roughened.

In addition, when as the laser beam applied in step S42, the one having what is called a top-hat shaped intensity distribution is employed, the alignment reference part 1m having a more uniform shape in a surface direction of the first main surface 1a can be formed. Thus, in the first main surface 1a, a boundary between the residual region 1e and the two alignment reference parts 1m can be clearly recognized. In this case, the positions of the two alignment reference parts 1m in the first main surface 1a can be very easily detected. Here, the top-hat shaped laser beam means a laser beam having almost the same beam energy intensity without regard to its position in a direction vertical to a traveling direction of the beam, that is, in the width direction of the beam, as shown in FIG. 17.

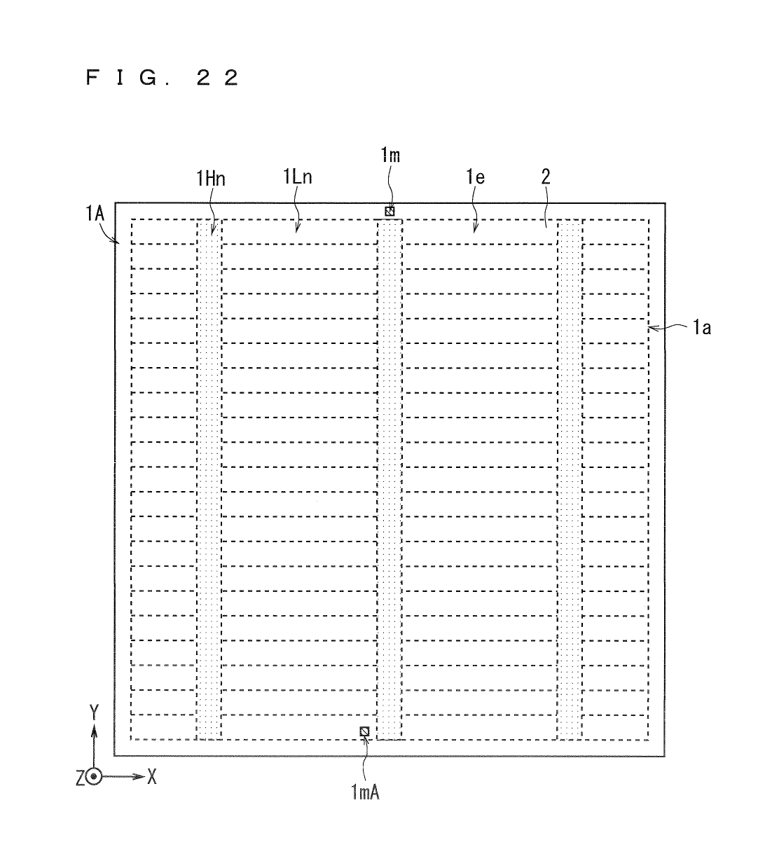

Then, in step S5 in FIG. 8, a step of removing the glass layer GL1 (also referred to as a removing step) provided on the first main surface 1a of the semiconductor substrate 1 is performed. Here, the glass layer GL1 can be removed by an etching process with hydrofluoric acid, for example. Thus, the semiconductor substrate 1 in which the second semiconductor region 1n is provided on the first main surface 1a side is formed (see FIG. 18). In addition, the two alignment reference parts 1m are provided on the surface part on the first main surface 1a side of the semiconductor substrate 1, as shown in FIG. 19. Here, in FIG. 19, a formed region of the first linear part 4b is shown by a broken line. Meanwhile, in FIG. 19, a formed region of the second linear part 4a is shown as a region surrounded by a broken line in FIG. 19. Note that, in a case where the second semiconductor region 1n is provided also on the second main surface 1b side in step S4, it may be removed by an etching process with fluonitric acid solution.

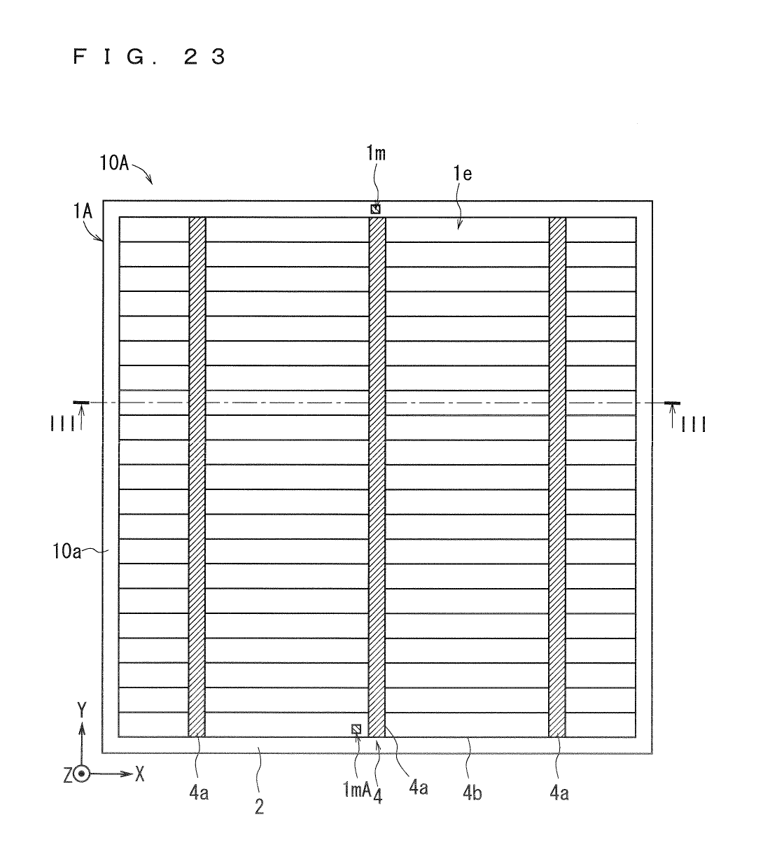

In step S6, the antireflection film 2 is formed on the first main surface 1a of the semiconductor substrate 1 (see FIG. 20). As a method of forming the antireflection film 2, a PECVD (plasma enhanced chemical vapor deposition) method, evaporation method, sputtering method, or the like can be employed, for example. For example, in the case where the PECVD method is employed, a mixture gas of SiH₄ gas and NH₃ gas is diluted with N₂ gas and plasma is generated by glow discharge decomposition in a chamber in a film forming apparatus, whereby silicon nitride is deposited on the first main surface 1a. Thus, the antireflection film 2 containing the silicon nitride can be formed. In addition, a temperature in the chamber when the silicon nitride is deposited may be about 500° C., for example. FIG. 21 shows an outer appearance of the first main surface 1a of the semiconductor substrate 1 on which the antireflection film 2 is provided. In addition, a broken line shown in FIG. 21 shows the same meaning as that in FIG. 19.

In step S7, an electrode forming step of forming the first electrode 4 and the second electrode 5 is performed.

Here, a method of forming the first electrode 4 will be described. The first electrode 4 is formed with a silver paste containing metal powder mainly containing silver or the like, organic vehicle, and glass frit, for example. More specifically, the silver paste is applied on the antireflection film 2 of the semiconductor substrate 1. At this time, in order to adjust the region in which the silver paste is applied, the two or more alignment reference parts 1m are used as reference. For example, under the condition that the semiconductor substrate 1 is set in an apparatus for applying the silver paste, the first main surface 1a is taken by an imaging apparatus. In the image processing performed for the image of the first main surface 1a taken at that time, a binarization process is performed, for example to detect the positions of the two alignment reference parts 1m. Thus, based on the detected positions of the two alignment reference parts 1m, the region in which the silver paste is applied in the first main surface 1a is adjusted.

Then, the silver paste applied on the first main surface 1a is fired, whereby the first electrode 4 is formed. Here, a maximum temperature at the time of the firing may be 600° C. or more and 800° C. or less. In addition, a time taken for the firing may be about several tens of seconds or more and about several tens of minutes or less. A method of applying the silver paste, a screen printing method or the like may be employed, for example. After the silver paste has been applied, the silver paste may be dried at a predetermined temperature, whereby a solvent in the silver paste may be evaporated. In addition, the first electrode 4 includes the first linear part 4b and the second linear part 4a, but when the screen printing method is employed, the first linear part 4b and the second linear part 4a can be formed at around the same time in the one step.

Next, a method of forming the second electrode 5 will be described. The collecting electrode 5b of the second electrode 5 is formed with an aluminum paste containing aluminum powder and organic vehicle, for example. Here, the aluminum paste is applied to almost a whole surface except for a part of portion in which the output extraction electrode 5a is formed in the second main surface 1b of the semiconductor substrate 1. Here, a method of applying the aluminum paste, a screen printing method or the like is employed, for example. Note that, after the aluminum paste has been applied on the second main surface 1b of the semiconductor substrate 1, a drying step may be performed so that a component of a solvent in the aluminum paste is evaporated at a predetermined temperature. Thus, the aluminum paste is not likely to be attached to the part other than the part in which it is to be applied, in each step after the drying step. As a result, workability in each step after the drying step can be enhanced.

The output extraction electrode 5a of the second electrode 5 is formed with a silver paste containing metal powder mainly containing silver powder or the like, organic vehicle, and glass frit, for example. Here, for example, after the aluminum paste has been applied on the second main surface 1b of the semiconductor substrate 1, the silver paste is applied on the second main surface 1b of the semiconductor substrate 1 so as to have a predetermined shape. At this time, the silver paste is applied to a position which is in contact with a part of the aluminum paste for forming the collecting electrode 5b. Thus, the output extraction electrode 5a is formed so as to overlap with the part of the collecting electrode 5b. Here, as a method of applying the silver paste, a screen printing method or the like is employed, for example. Note that, after the silver paste has been applied on the second main surface 1b of the semiconductor substrate 1, a drying step may be performed so that a component of a solvent in the silver paste is evaporated at a predetermined temperature.

Thus, the semiconductor substrate 1 on which the aluminum paste and the silver paste have been applied is subjected to a heat treatment such that it is held at a maximum temperature between 600° C. and 850° C. for a time about between several tens of seconds and several tens of minutes in a firing furnace. Thus, the aluminum paste and the silver paste are fired, whereby the second electrode 5 is formed. In addition, at this time, aluminum in the aluminum paste is diffused in the semiconductor substrate 1. Thus, the fourth concentration region 1Hp is formed on the second main surface 1b side of the semiconductor substrate 1.

Note that, here, the description has been given of the method of forming the first electrode 4 and the second electrode 5 by printing and firing, but the first electrode 4 and the second electrode 5 may be formed by another forming method such as vapor deposition method, sputtering method, plating method, or the like. In this case, the fourth concentration region 1Hp may be formed by heat diffusion of boron, gallium, aluminum, or the like before the first electrode 4 and the second electrode 5 are formed, for example.

As described above, according to the solar cell element 10 and the method of manufacturing the solar cell element in this embodiment, the diffused reflection of light is likely to be generated on the alignment reference part 1m. Therefore, through the first main surface 1a of the semiconductor substrate 1 provided with the antireflection film 2, an edge part of the alignment reference part 1m can be easily determined. As a result, the electrode can be formed with high accuracy, with reference to the alignment reference part 1m.

In addition, according to the technique in the Japanese Patent Application Laid-Open No. 2011-23690 (conventional technique), the linear surface electrode is formed on the pattern region having surface roughness smaller than that of a peripheral region, in the surface of the semiconductor substrate. Therefore, the linear surface electrode is likely to be removed from the semiconductor substrate. In addition, a contact area between the surface electrode and the semiconductor substrate is reduced, and contact resistance between the surface electrode and the semiconductor substrate could be increased.

Meanwhile, according to the solar cell element 10 in this embodiment, the concavo-convex part 1aL is formed in the formed region in which the first electrode 4 is formed in the first main surface 1a of the semiconductor substrate 1, similar to the peripheral region. Therefore, the problem that the first electrode 4 is likely to be removed from the semiconductor substrate 1 can be reduced. In addition, an increasing of the contact resistance due to the reduction in contact area between the first electrode 4 and the semiconductor substrate 1 can be also reduced.

Furthermore, according to the above conventional technique, in the surface of the semiconductor substrate, as for the peripheral region other than the pattern region, the light confinement effect is properly provided by the concavo-convex shape, but as for the pattern region, the concavo-convex shape is broken and the light confinement effect is not sufficiently provided, so that the conversion efficiency of the solar cell element could be reduced.

Meanwhile, according to the solar cell element 10 in this embodiment, the two or more alignment reference parts 1m are small in size, so that a lowering of the conversion efficiency of the solar cell element can be reduced. Especially, when the alignment reference part 1m is positioned in the region on the extended line virtually extended from the second linear part 4a in the +Y direction, for example, in which the light is blocked by the wiring member 101 when the solar cell module 100 is manufactured, the lowering of the conversion efficiency of the solar cell element 10 can be further reduced.

<(2) Variation>

Note that, the present invention is not limited to the above embodiment, and various modifications, improvements, and the like can be made without departing from the scope of the invention.

For example, according to the above embodiment, the two alignment reference parts 1m are positioned in the region on the extended line virtually extended from the second linear part 4a in the ±Y direction, but the present invention is not limited to this. The two or more alignment reference parts 1m may be provided in two or more positions apart from each other in the surface part on the first main surface 1a side of the semiconductor substrate 1.

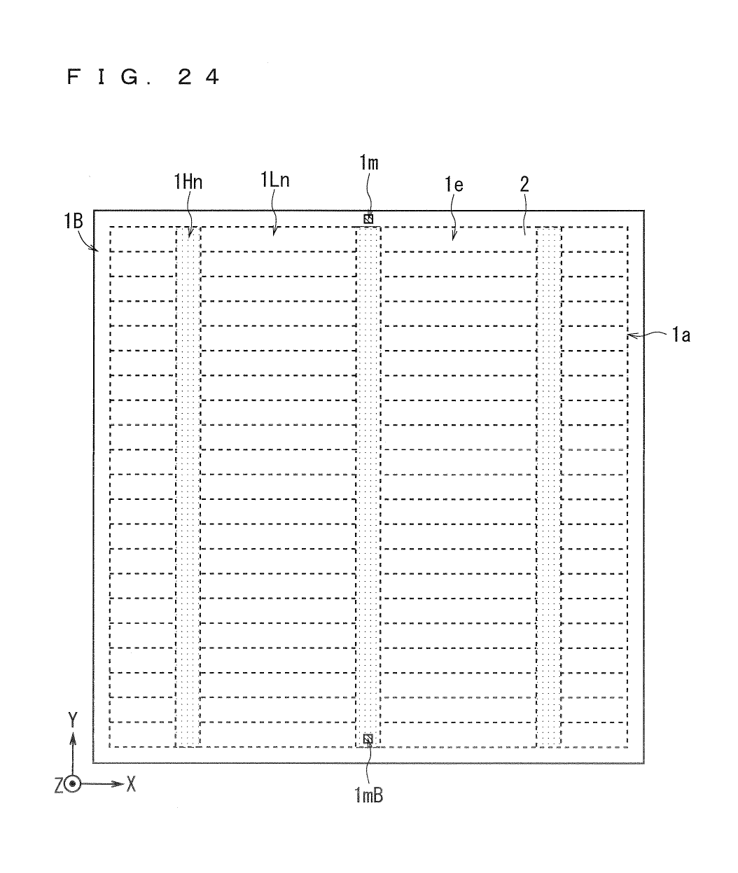

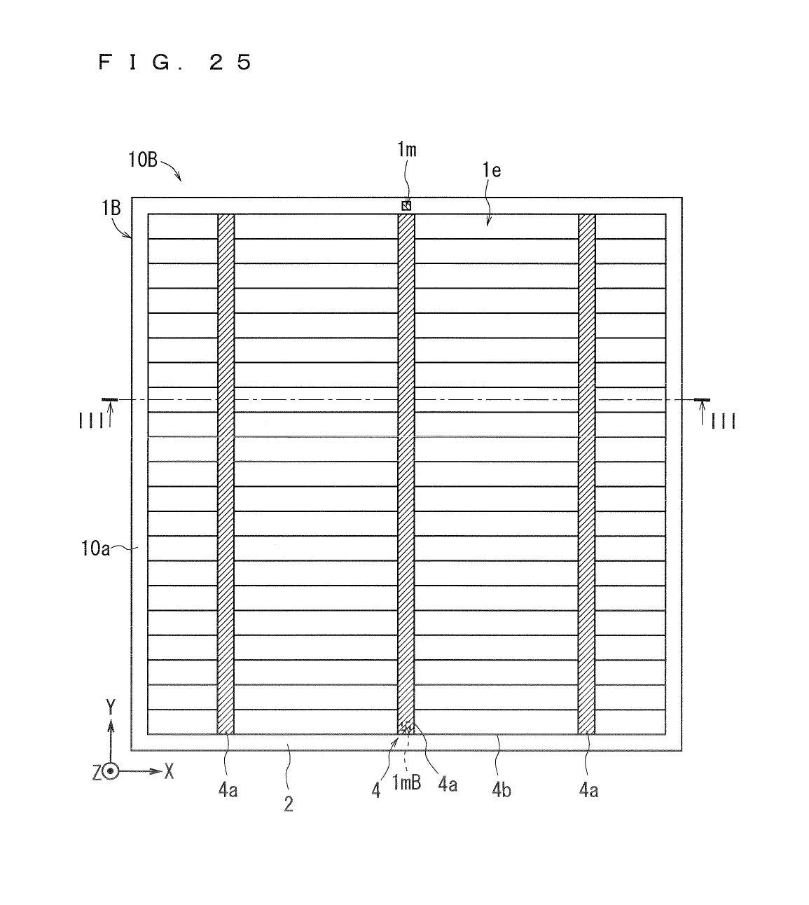

For example, a configuration can be employed such that the one or more alignment reference parts 1m among the two or more alignment reference parts 1m are positioned on the first concentration region 1Ln of the first main surface 1a. More specifically, as shown in FIG. 22, for example, a configuration can be employed such that an alignment reference part 1mA is positioned on the first concentration region 1Ln other than the second concentration region 1Hn to be provided with the first electrode 4, in the first main surface 1a of a semiconductor substrate 1A. In this case, a solar cell element 10A can be manufactured as shown in FIG. 23. Thus, when such a configuration is employed, the alignment reference part 1mA provided in the position other than the second concentration region 1Hn in the first main surface 1a can be easily recognized by the imaging, the binalization process and the like. As a result, the first electrode 4 can be formed with high accuracy. In addition, when such a configuration is employed, even after the first electrode 4 has been formed on the first main surface 1a of the semiconductor substrate 1A, the alignment reference part 1mA can be easily recognized. Thus, the alignment reference part 1mA can be used for positioning in the step after the step of forming the first electrode 4, that is, in the step of connecting the wiring member 101 or the like, for example. As a result, the wiring member 101 can be connected to the first electrode 4 and the second electrode 5 with high accuracy.

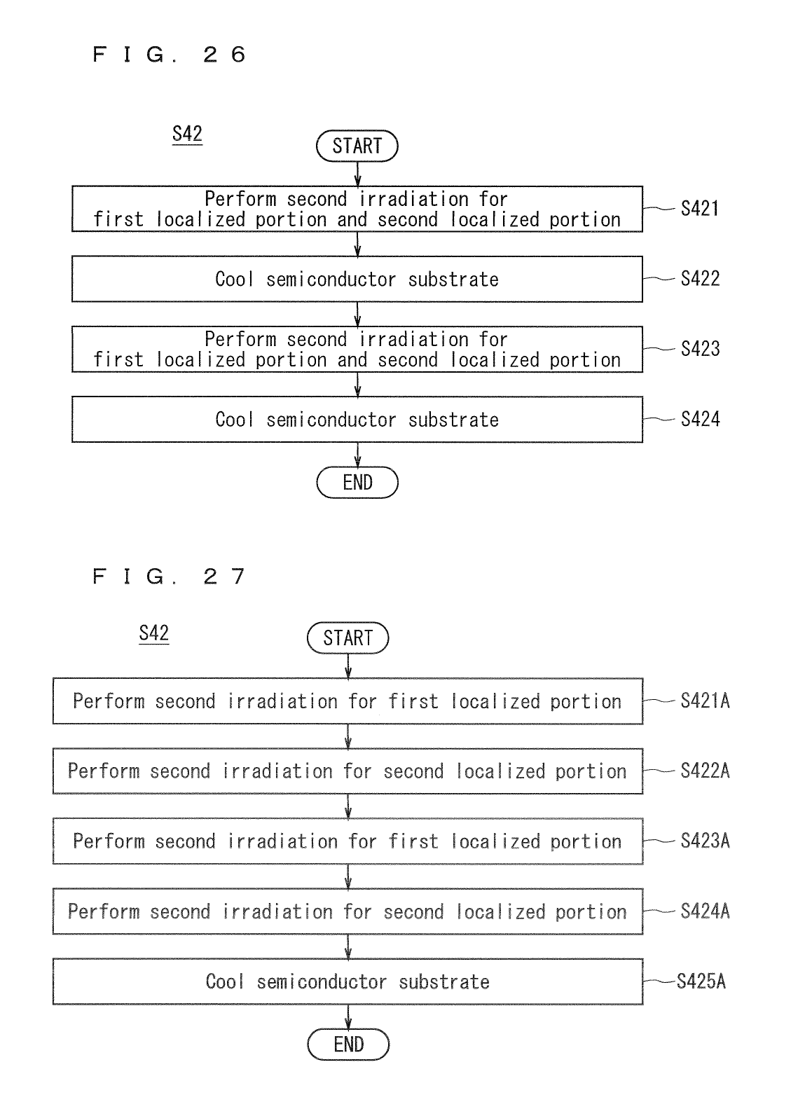

In addition, a configuration can be employed such that the one or more alignment reference parts 1m among the two or more alignment reference parts 1m are positioned on the second concentration region 1Hn of the first main surface 1a. More specifically, as shown in FIG. 24, for example, a configuration can be employed such that an alignment reference part 1mB is positioned on the second concentration region 1Hn provided with the forming target region of the first electrode 4, in the first main surface 1a of a semiconductor substrate 1B. In this case, a solar cell element 10B can be manufactured as shown in FIG. 25. Thus, when such a configuration is employed, light reception in the first main surface 1a is hardly reduced in spite of the presence of the alignment reference part 1mB. As a result, conversion efficiency in the solar cell element 10B can be increased. In addition, since the first electrode 4 is provided on the alignment reference part 1mB having large surface roughness, the first electrode 4 is not likely to be removed from the semiconductor substrate 1B due to an anchor effect. Thus, reliability in the solar cell element 10B can be improved.

In addition, as shown in the above embodiment, the configuration can be employed such that the one or more alignment reference parts 1m among the two or more alignment reference parts 1m are positioned in the region on the extended line virtually extended from the second linear part 4a in the Y direction. Furthermore, the two or more alignment reference parts 1m may be positioned in the regions on the extended lines virtually extended from the two or more second linear parts 4a in the Y direction, in the first main surface 1a. When such a configuration is employed, the two or more alignment reference parts 1m are positioned in the positions in which the light is blocked by the wiring member 101 when the solar cell module 100 is manufactured. Thus, reductions of an amount of the light received and the power generation efficiency can be reduced in the solar cell element 10.

In addition, according to the above embodiment, the alignment reference part 1m is formed after the second concentration region 1Hn has been formed, but the present invention is not limited to this. For example, the first concentration region 1Ln, the second concentration region 1Hn, and the alignment reference part 1m are not necessarily formed in this order, but may be formed in any order. That is, the alignment reference part 1m may be formed by local heating under the condition that the glass layer GL1 is provided on the first main surface 1a of the semiconductor substrate 1.

Furthermore, according to the above embodiment, in the roughening step in step S42, the second irradiation of the laser beam is simply performed to the same position more times than that of the first irradiation of the laser beam in step S412, but the present invention is not limited to this. For example, a configuration may be employed such that the second irradiation is performed to the same position several times, and the semiconductor substrate 1 is cooled while the second irradiation is performed several times. When such a configuration is employed, the semiconductor substrate 1 is cooled between timing of the certain second irradiation and timing of the next second irradiation. Thus, the semiconductor substrate 1 is not locally heated in an excessive manner, so that a crack due to the excessive heating is less likely to generate in the semiconductor substrate 1. In addition, here, the second irradiation is performed such that the laser beam may be continuously applied to the same position 50 to 5000 times for a time between 0.005 second and 0.5 second. In addition, the number of the times of the second irradiation for the same position may be between 2 and 10, for example. Here, a description will be given of a specific case where the semiconductor substrate 1 is cooled while the second irradiation is performed several times.

For example, as shown in FIG. 26, in step S42, a configuration in which the processes in steps S421 to S424 are sequentially performed is supposed. In step S421, the second irradiation is performed from above the glass layer GL1 for each of the two or more localized portions apart from each other in the one main surface 1a of the semiconductor substrate 1. At this time, the second irradiation may be performed for the two or more localized portions at around the same time, or the second irradiation may be performed sequentially for them. In step S422, the semiconductor substrate 1 is cooled. At this time, the two or more localized portions of the semiconductor substrate 1 can be cooled by air cooling, spraying a gas or the like, for example. In step S423, similar to step S421, the second irradiation is performed from above the glass layer GL1 for the two or more localized portions of the semiconductor substrate 1. In step S424, similar to step S422, the semiconductor substrate 1 is cooled. In addition, the second irradiation and cooling may be repeated three or more times for each localized portion.

In addition, a configuration is conceived such that while the second irradiation is performed for a first localized portion of the one main surface 1a of the semiconductor substrate 1 several times, the second irradiation is performed for one or more localized portions apart from the first localized portion in the one main surface 1a of the semiconductor substrate 1. That is, the configuration is conceived such that the process in which the second irradiation is sequentially performed for the two or more localized portions apart from each other in the one main surface 1a of the semiconductor substrate 1 is repeated at least two times. In addition, here, the second irradiation is sequentially performed for the two or more localized portions in such a manner that the laser beam is deviated by a galvanometer minor or the like.

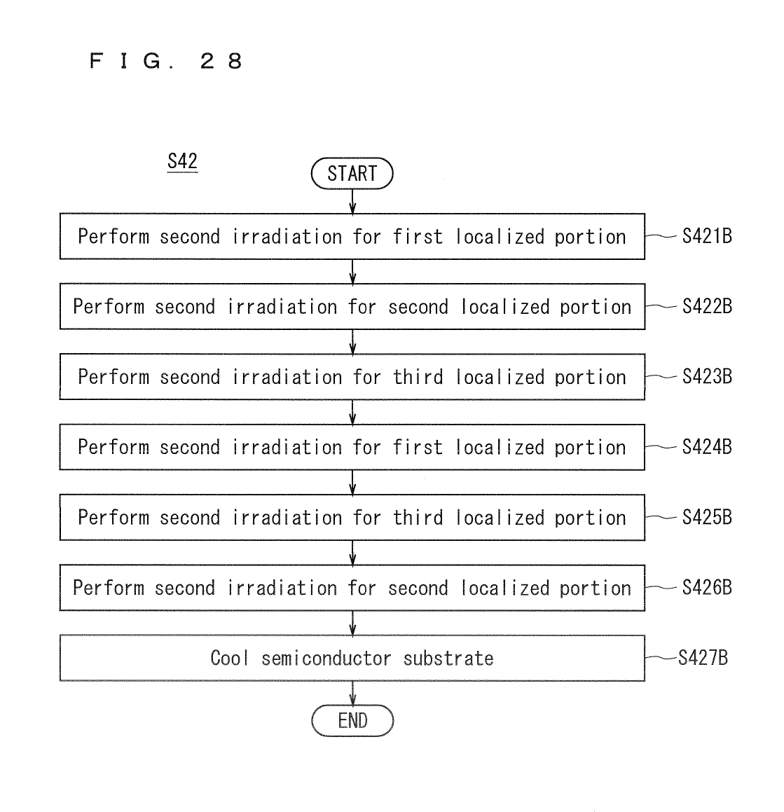

More specifically, the configuration is conceived such that the second irradiation is alternately performed for the two localized portions. For example, as shown in FIG. 27, a configuration is conceived such that the processes in steps S421A to S425A are sequentially performed in step S42. In step 421A, the second irradiation is performed from the glass layer GL1 for the first localized portion. In step 422A, the second irradiation is performed from above the glass layer GL1 for a second localized portion apart from the first localized portion, in the one main surface 1a of the semiconductor substrate 1. At this time, the first localized portion of the semiconductor substrate 1 is cooled. In step 423A, the second irradiation is performed from above the glass layer GL1 for the first localized portion. At this time, the second localized portion of the semiconductor substrate 1 is cooled. In step 424A, the second irradiation is performed from above the glass layer GL1 for the second localized portion. At this time, the first localized portion of the semiconductor substrate 1 is cooled. In step S425A, the whole of the semiconductor substrate 1 is cooled.

In addition, a configuration is conceived such that a process of one cycle in which the second irradiation is sequentially performed for three or more localized portions is repeated two or more times. However, an order of the second irradiation to be performed for the three or more localized portions in one cycle may be the same in all cycles or may be different in each cycle.

More specifically, a configuration is conceived such that a process of one cycle in which the second irradiation is performed for the first localized portion, the second localized portion, and a third localized portion apart from each other in this order in the one main surface 1a of the semiconductor substrate 1 is repeated two or more times. In addition, a configuration is conceived such that processes of two or more cycles in which the second irradiation is performed for the first localized portion, the second localized portion, and the third localized portion in a different order in each cycle are performed. In this case, a configuration is conceived such that in the process of a first cycle, the second irradiation is performed for the first localized portion, the second localized portion, and the third localized portion, in this order, and in the process of a second cycle, the second irradiation is performed for the first localized portion, the third localized portion, and the second localized portion in this order. For example, as shown in FIG. 28, steps S421B to S427B may be performed in step S42. In step 421B, the second irradiation is performed for the first localized portion from above the glass layer GL1. In step 422B, the second irradiation is performed for the second localized portion from above the glass layer GL1. At this time, the first localized portion of the semiconductor substrate 1 is cooled. In step 423B, the second irradiation is performed for the third localized portion from above the glass layer GL1. At this time, the first localized portion and the second localized portion of the semiconductor substrate 1 are cooled. In step 424B, the second irradiation is performed for the first localized portion from above the glass layer GL1. At this time, the second localized portion and the third localized portion of the semiconductor substrate 1 are cooled. In step 425B, the second irradiation is performed for the third localized portion from above the glass layer GL1. At this time, the first localized portion and the second localized portion of the semiconductor substrate 1 are cooled. In step 426B, the second irradiation is performed for the second localized portion from above the glass layer GL1. At this time, the first localized portion and the third localized portion of the semiconductor substrate 1 are cooled. In step S427B, the whole of the semiconductor substrate 1 is cooled.

In addition, the whole or one part of the above embodiment and the various variations can be appropriately combined in a consistent range, as a matter of course.

What is claimed is:

1. A method of manufacturing a solar cell element comprising:
preparing a semiconductor substrate;
forming a glass layer containing one conductivity type dopant, on one main surface of the semiconductor substrate;
forming one conductivity type semiconductor region including a first concentration region having a first concentration as a dopant concentration, and a second concentration region having a second concentration as a dopant concentration higher than the first concentration by heating the semiconductor substrate provided with the glass layer on the one main surface to diffuse the dopant in a surface part on the one main surface side of the semiconductor substrate; and
roughening surfaces of two or more portions apart from each other in the surface part on the one main surface side of the semiconductor substrate by locally heating the semiconductor substrate from above the glass layer, to form the alignment reference parts.

2. The method of manufacturing the solar cell element according to claim 1, wherein
in the forming the one conductivity type semiconductor region, the second concentration region is formed by performing first irradiation for irradiating one part of the semiconductor substrate from above the glass layer with a laser beam to heat the one part, and
in the roughening, by performing second irradiation for irradiating the semiconductor substrate from above the glass layer with the laser beam more times than that of the first irradiation, the semiconductor substrate is locally heated to form the alignment reference part.

3. The method of manufacturing the solar cell element according to claim 2, wherein
in the roughening, the second irradiation is performed several times, and the semiconductor substrate is cooled between the second irradiations performed several times.

4. The method of manufacturing the solar cell element according to claim 3, wherein
in the roughening, a process to sequentially perform the second irradiation for two or more localized portions apart from each other on the one main surface side of the semiconductor substrate is repeated at least two times.

5. The method of manufacturing the solar cell element according to claim 2, wherein
in the roughening, the laser beam having a top-hat type intensity distribution is used in the second irradiation.

6. A solar cell element manufactured by the method of manufacturing the solar cell element according to claim 1, comprising:
a semiconductor substrate including the first concentration region having the first concentration as the one conductivity type dopant concentration, and the second concentration region having a concentration higher than that of the first concentration region, as the one conductivity type dopant concentration, other than the first concentration region, in the surface part of the one main surface side;
an antireflection film provided on the first concentration region of the one main surface; and
an electrode provided on the second concentration region of the one main surface, wherein
two or more alignment reference parts apart from each other are provided in the surface part of the semiconductor substrate, and
a first surface roughness of the one main surface in the two or more alignment reference parts is larger than a second surface roughness of the one main surface other than the alignment reference parts.

7. The solar cell element according to claim 6, wherein
a void ratio of the surface part in each of the two or more alignment reference parts is larger than a void ratio of the surface part other than the alignment reference parts.

8. The solar cell element according to claim 6, wherein
each of the two or more alignment reference parts comprises an aggregated part including a plurality of aggregated granular parts.

9. The solar cell element according to claim 6, wherein
the antireflection film is provided on the one main surface in each of the two or more alignment reference parts, and a thickness of the antireflection film provided on the one main surface in the alignment reference parts is smaller than a thickness of the antireflection film provided on the one main surface other than the alignment reference parts.

10. The solar cell element according to claim 6, wherein
the one or more alignment reference parts among the two or more alignment reference parts are positioned on the second concentration region of the one main surface.

11. The solar cell element according to claim 6, wherein
the one or more alignment reference parts among the two or more alignment reference parts are positioned on the first concentration region of the one main surface.

12. The solar cell element according to claim 6, wherein
the electrode includes a plurality of first linear parts extending in a first direction, and a second linear part extending in a second direction different from the first direction, and intersecting with the plurality of the first linear parts,
a width of the second linear part is larger than a width of each of the first linear parts, and
the one or more alignment reference parts among the two or more alignment reference parts are positioned in a region on an extended line virtually extended from the second linear part in the second direction, in the one main surface.

13. The solar cell element according to claim 6, wherein
a first oxygen concentration of the surface part in the alignment reference part is higher than a second oxygen concentration of the surface part other than the alignment reference part.
